(19) United States
(12) Patent Application Publication
(10) Pub. No.: US 2009/0165877 A1
(43) Pub. Date: Jul. 2, 2009

(54) ACTUATOR ELEMENTS FOR MICROFLUIDICS, RESPONSIVE TO MULTIPLE STIMULI

(75) Inventors: Jacob Marinus Jan Den Toonder, Eindhoven (NL); Dirk Jan Broer, Eindhoven (NL); Auke Ronald Van Dijken, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/278,417

(22) PCT Filed: Feb. 1, 2007
(86) PCT No.: PCT/IB2007/050340

§ 371 Date: Aug. 6, 2008

(30) Foreign Application Priority Data
Feb. 7, 2006 (EP) 06101358.7

(51) Int. Cl. B81B 7/02; F15C 3/00; B81C 1/00

(52) U.S. Cl. 137/831; 137/827; 29/888; 29/890.09

(57) ABSTRACT

A micro-fluidic system comprises at least one micro-channel having a wall (14), a plurality of ciliary actuator elements (71) attached to said wall (14), said ciliary actuator elements (71) having an original shape when not subjected to a liquid, and means for applying stimuli to said plurality of ciliary actuator elements (71) so as to cause a change in their shape from an initial shape to an end shape. The ciliary actuator elements (71) are adapted to respond to the presence of a particular liquid by changing their original shape into the initial shape. The response to the presence of the particular liquid may be a curving of the original shape of the ciliary actuator element. Application of stimuli to the plurality of ciliary actuator elements provides a way to locally manipulate the flow of complex fluids in a micro-fluidic system.

The present invention relates to micro-fluidic systems, to a method for the manufacturing of such a micro-fluidic system and to a method for controlling or manipulating a fluid flow through micro-channels of such a micro-fluidic system. The micro-fluidic systems may be used in biotechnological and pharmaceutical applications and in micro-channel cooling systems in microelectronics applications.

Microfluidics relates to a multidisciplinary field comprising physics, chemistry, engineering and biotechnology that studies the behaviour of fluids at volumes thousands of times smaller than a common droplet. Microfluidic components form the basis of so-called “lab-on-a-chip” devices or biochip networks, that can process microliter and nanoliter volumes of fluid and conduct highly sensitive analytical measurements. The fabrication techniques used to construct microfluidic devices are relatively inexpensive and are amenable both to highly elaborate, multiplexed devices and also to mass production. In a manner similar to that for microelectronics, microfluidic technologies enable the fabrication of highly integrated devices for performing several different functions on a same substrate chip.

Micro-fluidic chips are becoming a key foundation to many of today's fast-growing biotechnologies, such as rapid DNA separation and sizing, cell manipulation, cell sorting and molecule detection. Micro-fluidic chip-based technologies offer many advantages over their traditional macrosized counterparts. Microfluidics is a critical component in, amongst others, gene chip and protein chip development efforts.

In all micro-fluidic devices, there is a basic need for controlling the fluid flow, that is, fluids must be transported, mixed, separated and directed through a micro-channel system consisting of channels with a typical width of about 0.1 mm or smaller. A challenge in microfluidic actuation is to design a compact and reliable micro-fluidic system for regulating or manipulating the flow of complex fluids of variable composition, e.g. saliva and full blood, in micro-channels. Various actuation mechanisms have been developed and are at present used, such as, for example, pressure-driven schemes, micro-fabricated mechanical valves and pumps, inkjet-type pumps, electro-kinetically controlled flows, and surface-acoustic waves.

In US 2003/0142901, an actuation method for microfluidics is provided. This method operates by controlling changes in the chemical affinity of capillaries. This method comprises the deposition of a nanolayer of a material on the inside wall of said capillaries and the application of an external stimulus to said capillaries. External stimuli such as described in US 2003/0142901 are a voltage, a change in an applied voltage, a magnetic field, removal of a magnetic field, a change in capacitance, application or removal of an electrostatic field among others. The principle of the described method relies on the shift of the nanolayer from a first conformation state to a second conformation state upon application of the stimulus. Conformation states such as described in this prior art document are typically molecular conformation changes such as a change from a cis to a trans configured double bond, rotating a molecular group about an axis or bending and unbending a molecular chain. When the chemical affinity of capillaries coated with such a nanolayer is changed, a control of the direction or the speed of flow through said capillaries is enabled. For instance, US 2003/0142901 proposes to flip progressively the conformation along a channel in order to create a conveyor for a droplet of a fluid.

A disadvantage, however, of using this method to convey a liquid through a channel in a microfluidic device is that the used nanolayer, being extremely thin, is likely to suffer rapidly from aging (e.g. via erosion or migration of the nanolayer under the surface of the channel). Another disadvantage is that such a system is unable to drive a continuous flow of fluid through a channel and is limited to the transport of droplets.

It is an object of the present invention to provide an improved alternative micro-fluidic system and method of manufacturing and operating the same. Advantages of the present invention can be at least one of being compact, cheap and easy to process.

The above objective is accomplished by a method and device according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect, the present invention provides a micro-fluidic system comprising at least one micro-channel having a wall with an inner side, wherein the micro-fluidic system furthermore comprises:

a plurality of ciliary actuator elements attached to said inner side of said wall, each ciliary actuator element having an original shape when not subjected to a liquid, and

means for applying stimuli to said plurality of ciliary actuator elements so as to cause a change in their shape and/or orientation from an initial shape and/or orientation to an end shape and/or orientation.

The ciliary actuator elements are adapted to respond to the presence of a particular liquid, e.g. water, by changing their shape from the original shape and/or orientation into the initial shape and/or orientation. The response to the presence of said particular liquid may be a curving of the original shape of the ciliary actuator element.

Application of stimuli to the plurality of ciliary actuator elements provides a way to locally manipulate the flow of complex fluids in a micro-fluidic system. The actuator elements may be driven or addressed individually or in groups to achieve specific ways of fluid flow.

The advantage of the proposed combination of liquid-induced shape-change and external stimuli being applied to the plurality of actuator elements is that the initial shape of the actuator elements is automatically triggered by bringing the elements in contact with a liquid-based, e.g. water-based, environment, such as in a micofludic biosensor which may include a biosensor chip. The initial shape preferably is a curved shape. This curved shape remains the natural non-actuated state as long as the liquid-environment is maintained.

In a preferred embodiment according to the present invention, the actuator elements may be polymer actuator elements and may for example comprise polymer MEMS. Polymer materials are, generally, tough instead of brittle, relatively cheap, elastic up to large strains (even up to 100%) and offer perspective of being processable on large surface areas with simple processes. Therefore, they are particularly suitable for being used to form actuator elements according to the present invention. In a most preferred embodiment according to the present invention, the actuator elements may change shape in presence of a particular liquid and may for example take a curved shape in presence of water. In this most preferred embodiment, the material used to form the ciliary actuator elements may be, or may comprise, one of a water responsive LC-polymer network material, a material presenting a gradient in polarity over its thickness or a two layer structure wherein one layer expands more in water than the other.

The means for applying a stimulus to the plurality of ciliary actuator elements may be one of an electric field generating means (e.g. a voltage source) or an external or internal magnetic field generating means.

In case of magnetic stimulation, the actuator elements may then comprise one of a uniform continuous magnetic layer, a patterned continuous magnetic layer, magnetic particles. In case of electrostatic stimulation, the actuator elements may comprise an electrode (e.g. a conductive layer).

In embodiments according to the invention, the plurality of ciliary actuator elements may be arranged in a first and second row, the first row of actuator elements being positioned at a first position of the inner side of the wall and the second row of actuator elements being positioned at a second position of the inner side of the wall, the first position and the second position being substantially opposite to each other.

In other embodiments of the present invention, the plurality of ciliary actuator elements may be arranged in a plurality of rows of actuator elements which may be arranged to form a two-dimensional array.

In further embodiments of the present invention, the plurality of ciliary actuator elements may be randomly arranged at the inner side of the wall of a microchannel.

In a second aspect according to the invention, a method for the manufacturing of a micro-fluidic system comprising at least one microchannel is provided. The method comprises:

providing an inner side of a wall of said at least one micro-channel with a plurality of ciliary actuator elements, the actuator elements having an original shape when not subjected to a liquid, and

providing means for applying a stimulus to said plurality of ciliary actuator elements so as to change the shape and/or orientation of the actuator elements from an initial shape and/or orientation to an end shape and/or orientation,

wherein the ciliary actuator elements respond to the presence of a particular liquid by changing their shape from the original shape into the initial shape.

Providing the ciliary actuator elements may be performed by the following steps:

depositing a sacrificial layer having a length L on the inner side of said wall,

depositing a actuator material on top of said sacrificial layer,

releasing said actuator material from said inner side of said wall by completely removing said sacrificial layer.

Removing the sacrificial layer may be performed by an etching step.

According to embodiments of the invention, the method may comprise providing ciliary actuator elements comprising at least one of the following:

a Liquid crystalline (LC) polymer network material or/and

a gradient in polarity over the thickness of the material used in said actuator or/and

a two-layer structure wherein one layer expands more in said liquid than the other.

According to embodiments of the invention, the method may furthermore comprise providing the ciliary actuator elements with one of a uniform continuous magnetic layer, a patterned continuous magnetic layer, magnetic particles or an electrode. The means for applying a stimulus to the ciliary actuator elements may comprise providing a magnetic field generating means or an electric field generating means.

In a further aspect of the present invention, a method for controlling a fluid flow through a microchannel of a micro-fluidic system is provided. The microchannel has a wall with an inner side. The method comprises:

providing said inner side of said wall with a plurality of ciliary actuator elements, the actuator elements each having an original shape and/or orientation,

applying a stimulus to said actuator elements so as to cause a change in their shape and/or orientation from an initial shape and/or orientation to an end shape and/or orientation,

wherein the ciliary actuator elements respond to the presence of a particular liquid by changing shape from the original shape to the initial shape.

In a specific embodiment according to the invention, applying a stimulus to the actuator elements may be performed by applying a magnetic field or by applying an electric field.

The present invention also includes, in a further aspect, a micro-fluidic system comprising at least one micro-channel having a wall with an inner side and containing a liquid, wherein the micro-fluidic system furthermore comprises:

a plurality of electroactive polymer actuator elements attached to the inner side of the wall, and

means for applying stimuli to the plurality of electroactive polymer actuator elements so as to drive the liquid in a direction along the micro-channel,

wherein the actuator elements respond to the presence of said liquid by changing their shape.

The electroactive polymer actuator element may comprise a polymer gel, an Ionomeric Polymer-Metal composite (IPMC), or another suitable electroactive polymer material.

The micro-fluidic system according to the invention may be used in biotechnological, pharmaceutical, electrical or electronic applications.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

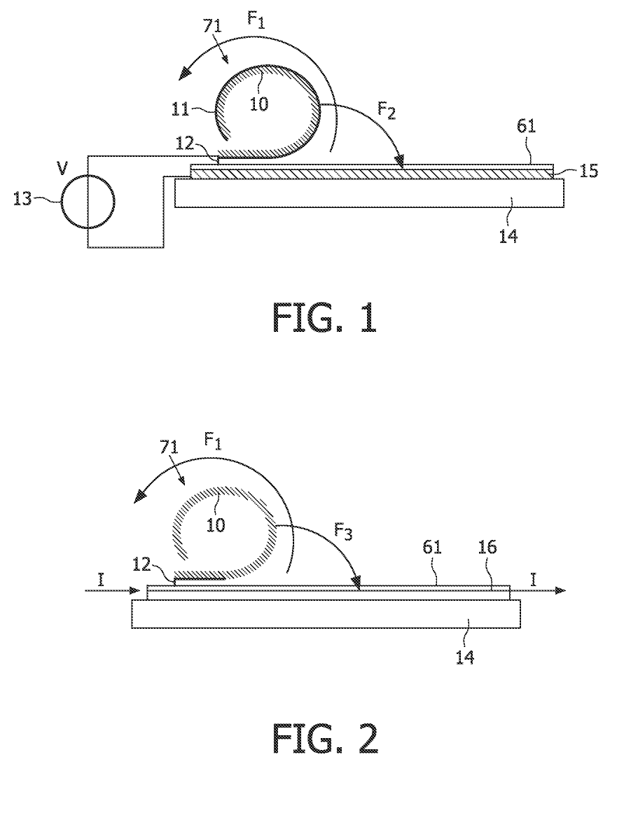

FIG. 1 is a schematic illustration of a cross-section of a part of a micro-channel having the inner-side of its wall covered with a curved polymer actuator element onto which an electric field may be applied, according to an embodiment of the present invention.

FIG. 2 is a schematic illustration of a cross-section of a part of a micro-channel having the inner-side of its wall covered with a curved polymer actuator element onto which a magnetic field generated by a conductive line may be applied, according to an embodiment of the present invention.

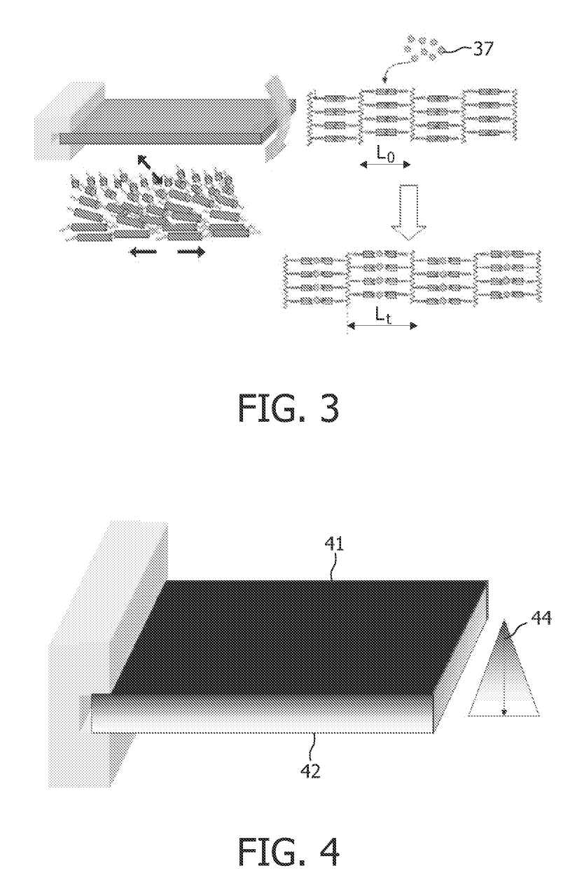

FIG. 3 illustrates the influence of water on the shape of a polymer actuator element including LC-polymer networks as a material according to a specific embodiment of the invention.

FIG. 4 illustrates the gradient of polarity observed over the thickness of the material used in an actuator element according to a specific embodiment of the invention.

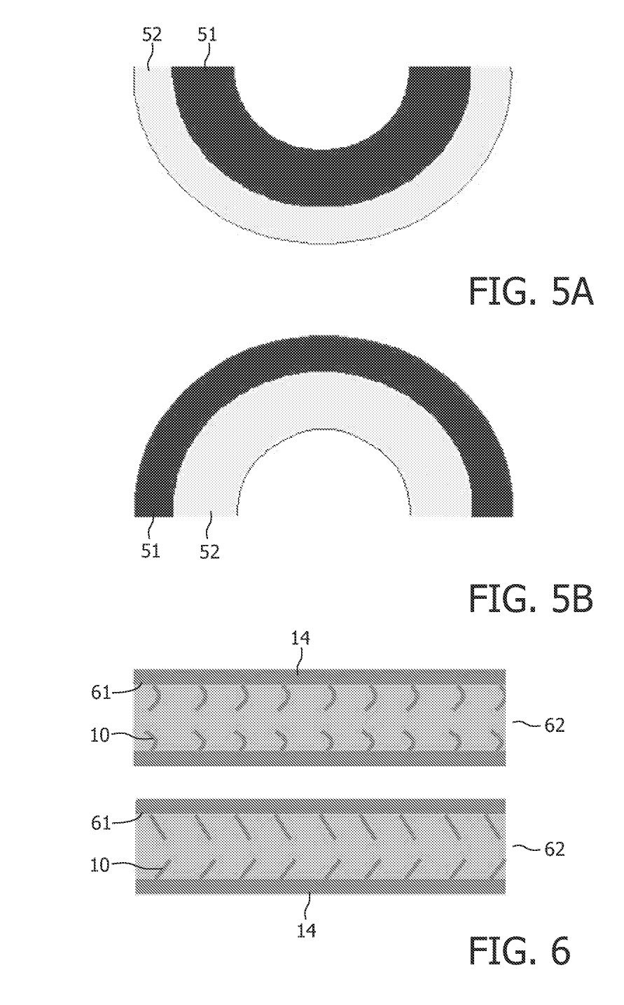

FIG. 5 illustrates the solvent polarity dependence of the bending of a polymer actuator element composed of two layers of different nature, according to a specific embodiment of the invention.

FIG. 6 is a schematic illustration of cross-sections of a micro-channel having the inner side of its wall covered with polymer actuator elements that curve up and straight out according to an embodiment of the invention.

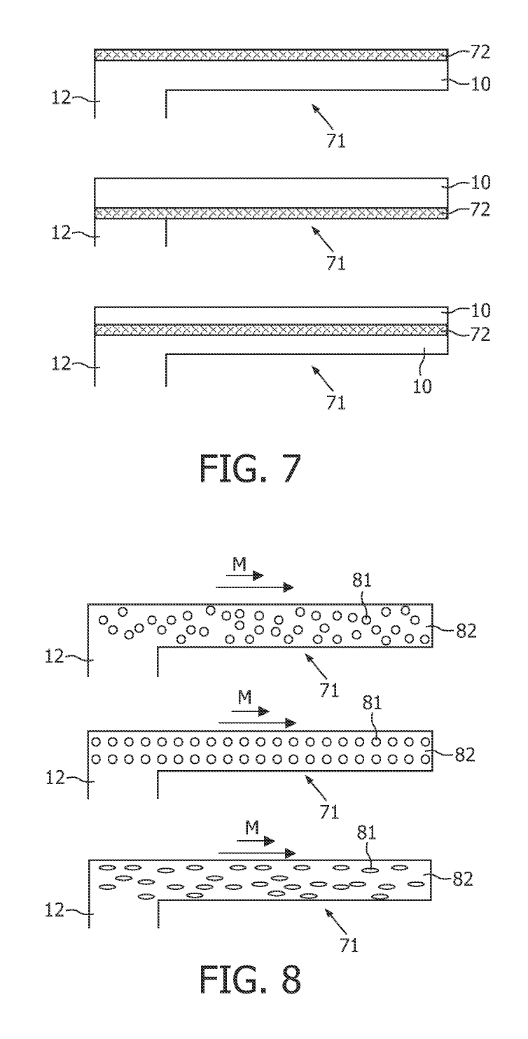

FIG. 7 illustrates a polymer actuator element comprising a continuous magnetic layer according to embodiments of the invention.

FIG. 8 illustrates a polymer actuator element comprising magnetic particles according to embodiments of the present invention.

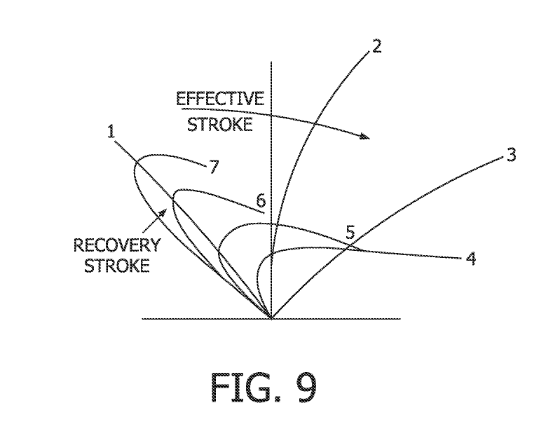

FIG. 9 illustrates an example of a ciliary beat cycle showing effective and recovery strokes.

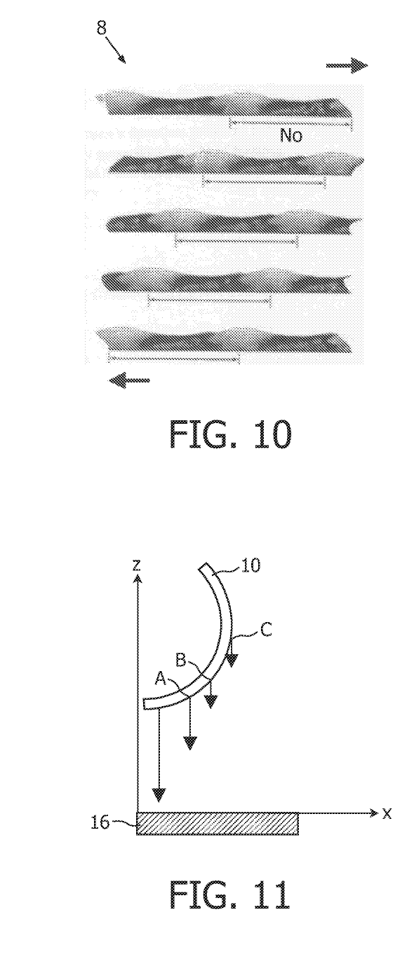

FIG. 10 illustrates a wave of cilia showing their co-ordination in a metachronic wave.

FIG. 11 illustrates the application of a non-uniform magnetic field using a conductive line to straighten out a polymer actuator element according to a further embodiment of the present invention.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

In a first aspect, the present invention provides a micro-fluidic system provided with means which allow transportation or (local) mixing or directing of fluids through micro-channels of the micro-fluidic system. In a second aspect, the present invention provides a method for the manufacturing of such a micro-fluidic system. In a third aspect, the present invention provides a method for controlling fluid flow through micro-channels of a micro-fluidic system. The micro-fluidic systems according to the invention are economical and simple to process, while also being robust and compact and suitable for very complex fluids.

In a first aspect of the present invention, a micro-fluidic system comprises at least one micro-channel and integrated micro-fluidic elements, also called integrated actuator elements or actuators, at an inner side of a wall of the at least one micro-channel. The actuator elements may be, for example, in any of the embodiments of the present invention unimorphs or bimorphs or multimorphs. The actuator elements have an original shape when not subjected to a liquid, i.e. in a dry non-actuated state. According to the present invention, the actuator elements are adapted to respond to the presence of a particular fluid by changing their shape. The actuator elements being in contact with the particular fluid is called a wet non-actuated state. In the wet non-actuated state, the original shape of the actuator elements is turned into an initial shape, which is the shape which will be started from for performing transportation or (local) mixing or directing of fluids through the at least one micro-channel of the micro-fluidic system. The micro-fluidic system furthermore comprises means for applying stimuli to said actuator elements so as to cause a change in their shape and/or orientation from an initial shape and/or orientation to an end shape and/or orientation. The change in shape and/or orientation from the initial shape to the end shape, depending on how the actuator elements are addressed, causes the transportation or (local) mixing or directing of the fluids through the at least one micro-channel of the micro-fluidic system. Thus, a liquid-based environment sets the initial deformed shape of the actuator elements, which can be a controlled curvature, whereas the external stimulus, e.g. magnetic or electrostatic stimulus, actively actuates the actuator elements by straightening them out. When the magnetic or electrostatic stimulus is removed, the elements return to their liquid-induced shape.

In one aspect of the invention, the way in which the micro-actuators, especially polymer micro-actuators according to the invention are envisioned to work, is inspired by nature. Nature knows various ways to manipulate fluids at small scales, i.e. 1-100 micron scales. One particular mechanism found is that due to a covering of beating cilia over the external surface of micro-organisms, such as, for example, paramecium, pleurobrachia, and opaline. Ciliary motile clearance is also used in the bronchia and nose of mammals to remove contaminants. A cilium can be seen as a small hair or flexible rod which in, for example, protozoa may have a typical length of 10 μm and a typical diameter of 0.1 μm, attached to a surface. Apart from a propulsion mechanism for micro-organisms, other functions of cilia are in cleansing of gills, feeding, excretion and reproduction. The human trachea, for example, is covered with cilia that transport mucus upwards and out of the lungs. Cilia are also used to produce feeding currents by sessile organisms that are attached to a rigid substrate by a long stalk. The combined action of the cilia movement with the periodic lengthening and shortening of the stalk induces a chaotic vortex. This results in chaotic filtration behaviour of the surrounding fluid.

The above discussion illustrates that cilia can be used for transporting and/or mixing fluid in micro-channels. The mechanics of ciliary motion and flow has interested both zoologists and fluid mechanists for many years. The beat of a single cilium can be separated into two distinct phases i.e. a fast effective stroke (curve 1 to 3 of FIG. 9) when the cilium drives fluid in a desired direction and a recovery stroke (curve 4 to 7 of FIG. 9) when the cilium seeks to minimise its influence on the generated fluid motion. In nature, fluid motion is caused by high concentrations of cilia in rows along and across the surface of an organism. The movements of adjacent cilia in one direction are out of phase, this phenomenon is called metachronism. Thus, the motion of cilia appears as a wave passing over the organism. FIG. 10 illustrates such a wave 8 of cilia showing their co-ordination in a metachronic wave (toward the left in FIG. 10). A model that describes the movement of fluid by cilia is published by J. Blake in ‘A model for the micro-structure in ciliated organisms’, J. Fluid. Mech. 55, p. 1-23 (1972). In this article, it is described that the influence of cilia on fluid flow is modelled by representing the cilia as a collection of “Stokeslets” along their centreline, which can be viewed as point forces within the fluid. The movement of these Stokeslets in time is prescribed, and the resulting fluid flow can be calculated. Not only the flow due to a single cilium can be calculated, also that due to a collection of cilia covering a single wall with an infinite fluid layer on top, moving according to a metachronic wave.

The approach a preferred aspect of the present invention makes use of is to mimic the cilia-like fluid manipulation in micro-channels by covering the walls of the micro-channels with “artificial cilia” based on microscopic actuator elements, which, according to the present invention, are structures changing their shape as a response to the presence of a liquid, and furthermore change their shape and/or orientation in response to a certain external stimulus. Hence, one aspect of the present invention provides a fluid flow device such as a pump having means for artificial ciliary metachronic activity. In the following description, these microscopic actuator elements such as polymer actuator elements may also be referred to as actuators, e.g. polymer actuators or micro-polymer actuators, actuator elements, micro-polymer actuator elements or polymer actuator elements. It has to be noticed that when any of these terms is used in the further description always the same microscopic actuator elements according to the invention are meant. For example micro-polymer actuator elements or polymer actuators can be set in motion, either individually or in groups, by either a magnetic or an electric field.

Actuator elements formed of one or more materials wherein at least one of said materials can respond to a liquid such as water to change the shape of the actuator elements into an initial shape upon contact with the liquid, and at least the same or another material forming the actuator elements is able to respond to an external stimulus such as an electrostatic field, magnetic field or electric field, may be used according to the present invention. Suitable materials able to respond to an external stimulus such as an electrostatic field, magnetic field or electric field can be identified from the book “Electroactive Polymer (EAP) Actuators as Artificial Muscles”, ed. Bar-Cohen, SPIE Press, 2004. An example of polymer material that may be used to form part of actuator elements which are being electrically stimulated may be a ferroelectric polymer, i.e. polyvinylidene fluorine (PVDF). Generally, all suitable polymers with low elastic stiffness and high dielectric constant may be used to induce large actuation strain by subjecting them to an electric field. Other suitable polymers may for example be Ionomeric Polymer-Metal Composite (IPMC) materials or e.g. perfluorsulfonate and perfluorcarbonate. If suitable materials, for example found in the above-mentioned book by Bar-Cohen, do not show a response to the presence of a liquid, they should be specifically adapted to do so, e.g. by adding another material which does show such response. Said adding another material may be done by combining two materials, or by providing multiple layers of different materials.

According to the invention, the integrated micro-fluidic elements may preferably be based on polymer materials. Suitable materials may be found in the above book by Bar-Cohen. However, also other materials may be used for the actuator elements. The materials that may be used to form actuator elements according to the present invention should be such that the formed actuator elements have the following characteristics:

the actuator element should be compliant, i.e. not stiff,

the actuator element should be tough, not brittle,

the actuator element should respond to a particular liquid by bending or otherwise changing shape,

the actuator elements should respond to either an electric field and/or a magnetic field by straightening out or changing shape, and

the actuator elements should be easy to process by means of relatively cheap processes.

Depending on the type of actuation stimulus, the material that is used to form the actuator elements may have to be functionalized. Considering the first, second and fifth characteristic of the above-summarised list, polymers are preferred for at least a part of the actuators, i.e. polymers may be used as a component of the actuators or polymers may be used as a layer of the actuators. Most types of polymers can be used according to embodiments of the present invention, except for very brittle polymers such as e.g. polystyrene which are not very suitable to use with the present invention. To enable electrostatic or magnetic actuation (see further), metals may be used to be part of the actuator elements, e.g. in Ionomeric Polymer-Metal composites (IPMC). For example, for magnetic actuation, FeNi or another magnetic material may be used to form part of the actuator elements. According to the invention, all suitable materials, i.e. materials that are able to change shape by, for example, mechanically deforming as a response to a liquid and as a response to an external stimulus such as an electrical stimulus and/or a magnetic stimulus, may be used. Traditional materials that show such mechanical response to an external stimulus, and that may be applied to form part of actuator elements for use in the methods according to the present invention, may be electro-active piezoelectric ceramics such as, for example, barium titanate, quartz or lead zirconate titanate (PZT). These materials may respond to an applied external stimulus, such as for example an applied electric field, by expanding. However, an important drawback of electro-active ceramics is that they are brittle, i.e. they fracture quite easily and they are hard to process as small structures. Furthermore, the processing technologies for electro-active ceramics are rather expensive and cannot be scaled up to large surface areas. Therefore, electro-active piezoelectric ceramics may only be suitable in a limited number of cases.

Other materials that can be used to be part of actuator elements according to the present invention include all forms of Electroactive Polymers (EAPs). They may be classified very generally into two classes: ionic and electronic. Electronically activated EAPs include any of electrostrictive (e.g. electrostrictive graft elastomers), electrostatic (dielectric), piezoelectric, magnetic, electrovisco-elastic, liquid crystal elastomer, and ferroelectric actuated polymers. Ionic EAPs include gels such as ionic polymer gels, Ionomeric Polymer-Metal Composites (IPMC), conductive polymers and carbon nanotubes. Any of the above EAPs can be made to bend or to straighten with a significant response and can be used in the form, for example, of ciliary actuators.

Suitable materials that can respond to a liquid such as water to change their shape include for instance all forms of liquid responsive polymers. These are polymers that are able to change shape and/or volume in presence of a particular liquid and are therefore, as mentioned above, particularly suitable to be used in the present invention in combination with materials able to respond to an external stimulus such as an electrostatic field, a magnetic field or an electric field. Among these liquid-responsive polymers, water responsive polymers are particularly suitable for use in the present invention. In particular, water-absorbing polymers which can expand in water can be used. A particularly suitable class of water absorbing polymers is hydrogels. Hydrogels is a class of cross-linked polymers and co-polymers that are able to absorb and retain water to a large extent (they can contain over 99% of water). Non-limitative examples of hydrogels that can be used with this invention are polyacrylamide, polyvinylpyrolidone, polyvinylalcool, polyacrylates and the like. Sub-classes of hydrogels can undergo phase transitions and considerable volume changes upon exposure to an external stimulus such as pH (e.g. 2-hydroxyethylmethacrylate-co-acrylic acid), chemical or biological agents, T° (e.g. Poly-N-isopropylacrylamide) or electric field. In some circumstances, said sub-class of hydrogels can be used in the present invention in order to introduce an additional control parameter in addition to the exposure to water and the magnetic or electric field.

Another class of water-responsive materials suitable for use in the present invention are polymeric materials presenting a gradient in polarity over their thickness.

Yet another class of water responsive materials which can be used within the scope of the present invention is a sub-class of liquid crystal (LC) polymer network materials. Said sub-class of LC polymer network materials is responsive to water in the sense that water molecules break bonds and therefore penetrate the network. Upon penetration of water, the LC material anisotropically swells in the direction of the LC molecules which can lead to the bending of the material if care has been taken during the processing to orient the LC molecules in a twisted manner over the thickness of the film.

Because of the above, according to the present invention, the actuator elements according to the present invention may preferably be formed of, or include as a part of their construction, polymer materials. Therefore, in the further description, the invention will be described by means of polymer actuator elements. It has, however, to be understood by a person skilled in the art that the present invention may also be applied when other materials than polymers, as described above, are used to form the actuator elements. Polymer materials are, generally, tough instead of brittle, relatively cheap, elastic up to large strains (up to 100%) and offer perspective of being processable on large surface areas with simple processes.

Hereinafter, three specific, non-limiting embodiments of the present invention will be described. In these specific embodiments, the polymer actuator elements 71 can change from a bended shape in wet, non-actuated condition to a straigthened shape in wet, actuated condition by either

a) applying an electric potential to electrodes 11 and 15 in or on the polymer Micro-Electro-Mechanical-Systems (polymer MEMS) 10 and the wall 14 respectively, as described hereinafter with reference to FIG. 1, or

b) applying an external magnetic field, either using an external means (e.g. via an (electro-)magnet) or using an internal means (e.g. via an integrated conductive wire or coil); this results in a magnetic force acting on magnetic layer(s) or particles in the polymer MEMS 10 as described hereinafter with reference to FIGS. 7 and 8, or

c) by combining a) and b)

In a first specific, non-limiting embodiment of the present invention, the upward curvature observed for the actuator element in liquid, e.g. aqueous, media when no electrical/magnetic stimulus is applied, i.e. in wet non-actuated state, is made possible by including LC-polymer network materials as a material in said actuator element. LC-polymer network materials can be made responsive to liquid such as water 37. FIG. 3 shows the principle for a polymer MEMS 10 made of an ordered LC-polymer network. A molecular length scale, L₀, of about 3 nm, characterises the material order. The LC molecules are sensitive to liquid, e.g. water molecules 37 in the sense that bonds are broken by the presence of the liquid, e.g. water molecules 37. The latter penetrate into the material, which responds by anisotropic swelling in the direction of the orientation of the LC molecules. Hence, the characteristic molecular length scale is increased to Lt as indicated in the right part of FIG. 3. Since, by careful processing, the orientation of the LC molecules twists over the thickness of the film, i.e. from one side of the beam to the other, the film responds by bending.

In a second specific, non-limiting embodiment of the present invention, the upward curvature observed for the actuator element in liquid, e.g. aqueous, media when no electrical/magnetic stimulus is applied, i.e. in wet non-actuated state, is made possible by creating a gradient in polarity 44 over the thickness of the material used in said actuator element 71. The principle is shown in FIG. 4. The starting point may be for instance a mixture of non-polar monomers and polar monomers, whereby the non-polar monomers (e.g. hexane diol diacrylate (HDDA)) react faster, than the polar monomers (e.g. hydroxypropyl acrylate) which react more slowly. Also a dye (e.g. 2-(2H-benzotriazol-2-yl)-4-(1,1,3,3-tetramethylbutyl)-6-(1-methyl-1-phenylethyl)phenol) and a photoinitiator (e.g. 2-methyl-1,2-diphenyl-1-propanone) are added. The film is cured by illumination thereof with UV light, from the top of the film. The dye present in the film will partially absorb the UV light, which causes a light intensity gradient 44 over the film thickness, the light intensity in the film being higher at the top than at the bottom. The cross-linking will start in regions with the highest intensity, i.e. at the top, and the fast reacting (apolar) molecules will crosslink first. During this process the more slowly reacting (polar) molecules will diffuse to the bottom and crosslink later. Hence, a fully crosslinked film with a polarity gradient 44 over its thickness is finally obtained, in this case having an apolar top surface 41 and a polar bottom surface 42. The result is that the film will curve upwards when being brought into a polar liquid such as water, and curve downwards when introduced in an apolar liquid.

In a third specific, non-limiting embodiment of the present invention (see FIG. 5), the upward curvature observed for the actuator element 71 in liquid, e.g. aqueous, media when no electrical/magnetic stimulus is applied, i.e. in wet non-actuated state, (situation A), is made possible by composing the Polymer MEMS 10 of two layers one of which expands in the liquid, e.g. water (layer 52) whereas the other one (layer 51) does not or does so to a lesser extent. This can, for example, be done by combining a hydrogel layer with another layer. If the polymer MEMS 10 is in presence of a non-polar liquid, the polymer MEMS will bend downward in a wet, non-actuated state (situation B). In a wet, actuated state, the actuator elements 71 can be made to be straightened.

In order to actuate the actuator elements 71 described in any of the three specific, non-limiting embodiments hereinabove, the actuator elements should be made responsive to either a magnetic field or an electric field.

To be able to actuate the actuator elements 71 by applying a magnetic field, the actuator elements 71 must be provided with magnetic properties. One way to provide a polymer actuator element 71 with magnetic properties is by incorporating a continuous magnetic layer 72 in the polymer actuator element 71, as shown in the different embodiments represented in FIG. 7. The actuator elements 71 with magnetic properties will in the further description be referred to as magnetic actuator elements 71. The continuous magnetic layer 72 may be positioned at the top (upper drawing of FIG. 7) or at the bottom of the actuator element 71 (drawing in the middle of FIG. 7), or may be situated in the centre of the actuator element 71 (lower drawing of FIG. 7). The position of the continuous magnetic layer 72, together with its wettability and its mechanical properties, determine the “natural” or non-actuated shape of the magnetic actuator element 71, i.e. curved upward or curved downward. The continuous magnetic layer 72 may, for example, be an electroplated permalloy (e.g. Ni—Fe) and may, for example, be deposited as a uniform layer. The continuous magnetic layer 72 may have a thickness of between 0.01 and 10 μm. The direction of easy magnetisation may be determined by the deposition process and may, in the example given, be the ‘in-plane’ direction. Instead of a uniform layer, the continuous magnetic layer 72 may also be patterned (not shown in the drawings) to increase the compliance and ease of deformation, e.g. curving, of the magnetic actuator elements 72.

Another way to achieve a magnetic actuator element 71 is by incorporating magnetic particles 81 in the polymer actuator element 71. The polymer may in that case function as a ‘matrix’ in which the magnetic particles 81 are dispersed, as is illustrated in FIG. 8, and will further be referred to as polymer matrix 82. The magnetic particles 81 may be added to the polymer in solution or may be added to monomers that, later on, then can be polymerised. In a subsequent step, the polymer may be applied to the inner side 61 of the wall 14 of the micro-channel 62 by any suitable method, e.g. by a wet deposition technique such as e.g. spin-coating. The magnetic particles 81 may for example be spherical, as illustrated in the upper two drawings in FIG. 8 or may be elongate, e.g. rod-shaped, as illustrated in the lower drawing in FIG. 8. The rod-shaped magnetic particles 81 may have the advantage that they may automatically be aligned by shear flow during the deposition process. The magnetic particles 81 may be randomly arranged in the polymer matrix 82, as illustrated in the upper and lower drawing of FIG. 8, or they may be arranged or aligned in the polymer matrix 82 in a regular pattern, e.g. in rows, as is illustrated in the drawing in the middle of FIG. 8. A scheme of a micro-channel 62 is provided in FIG. 6.

The magnetic particles 81 may, for example, be ferro- or ferri-magnetic particles, or (super)paramagnetic particles, comprising, for example, elements such as cobalt, nickel, iron or ferrite. In embodiments, the magnetic particles 81 may be superparamagnetic particles, i.e. they do not have a remanent magnetic field when an applied magnetic field has been switched off, During deposition, a magnetic field may be used to move and align the magnetic particles 81, such that the net magnetisation is directed in the length-direction of the magnetic actuator element 71.

The application of a magnetic field to the magnetic actuator elements 71 will then result in forces able to put the actuator elements 71 in motion i.e. to rotate, and/or to change shape. This force can result from an external magnetic field generating means such as, for example, a permanent magnet or an electromagnet placed outside the microfluidic system, or a local magnetic field generating means such as, for example, conductive lines 16 integrated in the micro-fluidic system (see FIG. 2).

The use of at least one conductive line 16 that may be integrated in the micro-fluidic system is illustrated in FIG. 2 and in FIG. 11. The conductive line or conductive lines 16 may, for example, be copper lines with a cross-sectional area of, for example, 1 to 100 μm². The magnetic field generated by a current through the conductive line 16 decreases with 1/r, r being the distance from the conductive line 16 to a position on the actuator element 71. For example, in FIG. 11, the magnetic field will be larger at position A than on position B of the actuator element 71. Similarly, the magnetic field at position B will be larger than the magnetic field on position C of the actuator element 71. Hence, \vec{H}₁>\vec{H}₂>\vec{H}₃. Therefore, the polymer actuator element 71 will experience a gradient in magnetic field along its length L. This will cause a “curling” motion of the magnetic actuator element 71, on top of its rotational motion. It can thus be imagined that, by combining a uniform magnetic “far field”, i.e. an externally generated magnetic field which is constant over the whole actuator element 71, the far field being either rotating or non-rotating, with conductive lines 16, it may be possible to create complex time-dependent magnetic fields that enable complex moving shapes of the actuator element 71. This may be very convenient, in particular for tuning the moving shape of the actuator elements 71 so as to get an optimised efficiency and effectiveness in fluid control.

FIG. 2 illustrates an example of a polymer actuator element 71 according to an embodiment of the present invention. The polymer actuator element 71 comprises a polymer Micro-Electro-Mechanical System (or polymer MEMS) 10 and an attachment means 12 for attaching the polymer MEMS 10 to the inner side 61 of a wall 14 of a micro-channel 62. In a dry state, the polymer MEMS 10 may be a straight device, e.g. a straight rod or beam or flap. When liquid, e.g. water, is present in the channel, the polymer MEMS 10 may be bending due to a force F₁ resulting from an internal mechanical moment in the actuator element, caused by the presence of liquid, e.g. water in its environment acting on its liquid sensitive, e.g. water sensitive, nature. This is the wet non-actuated state. A convenient actuator geometry that can be exploited in accordance with the present invention is where the actuator element is curved upwards in the wet non-actuated state. The actuator is rolled out by a magnetic force that has to overcome the counteracting force due to the internal mechanical movement. The magnetic force may be induced by a locally generated magnetic field, e.g. by a current wire or coil integrated into the substrate on which the actuator element is made, or by an external magnetic field (external permanent magnet or electromagnet). The arrow F₃ in FIG. 2 represents the actuation of the polymer MEMS 10 by a magnetic force generated by a current I flowing through an integrated conductive wire 16. This Force F₃ tends to straighten the polymer MEMS 10 when bringing it in the wet actuated state. Magnetic actuation will obviously only be effective if the actuator element can be magnetised. This can be achieved in various ways as described elsewhere in the present document. When the magnetic force is switched off, the actuator element will curve upward again due to a restoring force that brings the actuator back to its original wet non-actuated state.

FIG. 1 illustrates another example of a polymer actuator element 71 according to an embodiment of the present invention. Instead of magnetic actuation, electrostatic forces can be used to move the actuator elements. The polymer actuator element 71 comprises a polymer MEMS 10 including an electrode 11 (e.g. a conductive layer) and an attachment means 12 for attaching the polymer MEMS 10 to the inner side 61 of the wall 14 of a micro-channel 62 including a counterelectrode 15. In a dry state, i.e. without the presence of a liquid, the polymer MEMS 10 may be a straight device, e.g. a straight rod or beam or flap. The polymer MEMS 10 is bending due to a force F₁ resulting from an internal mechanical moment in the actuator element, caused by the presence of liquid, e.g. water, in its environment and acting on its liquid sensitive, e.g. water sensitive, nature. The arrow F₂ represents the actuation of the polymer MEMS 10 by an electrostatic force generated by an electrical potential difference V applied by a generator 13 between the electrode 11 and the counterelectrode 15. The electrostatic force thus generated on the element causes the element to move in the direction of the wall. In other words, this Force F₃ tends to straighten the polymer MEMS 10 thus bringing it in the wet actuated state.

One issue which may be controlled accurately is the initial shape, e.g. initial curve, i.e. the bending radius of the polymer actuating element in the non-actuated state. According to the present invention, this is done by using a material, preferably a polymer material, that changes shape in the presence of a liquid, e.g. water.

An embodiment of how to form an actuator element attached to the inner wall 61 of a micro-channel 62 according to the second aspect of the present invention will be described hereinafter.

The actuator elements 71 may be fixed to the inner side 61 of the wall 14 of a microchannel 62 in various possible ways. A first way to fix the actuator elements 71 to the inner side 61 of the wall 14 of a microchannel 62 is by depositing, for example by spinning, evaporation or by another suitable deposition technique on a sacrificial layer, a layer of material out of which the actuator elements 71 will be formed. Therefore, first a sacrificial layer may be deposited on an inner side 61 of a wall 14 of the micro-channel 62. The sacrificial layer may, for example, be composed of a metal (e.g. aluminium), an oxide (e.g. SiOx), a nitride (e.g. SixNy) or a polymer. The material the sacrificial layer is composed of should be such that it can be selectively etched with respect to the material the actuating element is formed of and may be deposited on an inner side 61 of a wall 14 of the micro-channel 62 over a suitable length. In some embodiments the sacrificial layer may, for example, be deposited over the whole surface area of the inner side 61 of the wall 14 of a microchannel 62, typically areas in the order of several cm. However, in other embodiments, the sacrificial layer may be deposited over a length L, which length L may then be the same length as the length of the actuator element 71, which may typically be between 10 to 100 μm. Depending on the material used, the sacrificial layer may have a thickness of between 0.1 and 10 μm.

In a next step, a layer of polymer material, which later will form the polymer MEMS 10, is deposited over the sacrificial layer and next to one side of the sacrificial layer. Thereafter, the layer of polymer material is selectively removed there where no polymer MEMS 10 should be present. Subsequently, the sacrificial layer may be removed by etching the sacrificial layer underneath the polymer MEMS 10. In that way, the polymer layer is released from the inner side 61 of the wall 14 over the length L, this part forming the polymer MEMS 10. The part of the polymer layer that stays attached to the inner side 61 of the wall 14 of the micro-channel 62 forms the attachment means 12 for attaching the polymer MEMS 10 to the micro-channel 62, more particularly to the inner side 61 of the wall 14 of the micro-channel 62.

Another way to form the actuator element 71 according to the present invention may be by using patterned surface energy engineering of the inner side 61 of the wall 14 of the micro-channel 62 before applying the polymer material. In that case, the inner side 61 of the wall 14 of the micro-channel 62 on which the actuator elements 71 will be attached is patterned in such a way that regions with different surface energies are obtained. This can be done with suitable techniques such as, for example, lithography or printing. Therefore, the layer of material out of which the actuator elements will be constructed is deposited and structured, each with suitable techniques known by a person skilled in the art. The layer will attach strongly to some areas of the inner side 61 of the wall 14 underneath, further referred to as strong adhesion areas, and weakly to other areas of the inner side 61 of the wall 14, further referred to as weak adhesion areas. It may then be possible to get spontaneous release of the layer at the weak adhesion areas, whereas the layer will remain fixed at the strong adhesion areas. The strong adhesion areas may then form the attachment means 12. In that way it is thus possible to obtain self-forming free-standing actuator elements 71.

The polymer MEMS 10, according to the present invention, are adapted to be response to the presence of a particular liquid, e.g. water. The polymer MEMS 10 may, for example, an acrylate polymer, a poly(ethylene glycol) polymer comprising copolymers, or may comprise any other suitable polymer. Adapting the polymer MEMS so as to be responsive to the presence of a particular liquid may be done by providing a material component responsive to the presence of a particular liquid, for mixing with a non-responsive material component, or by providing, on top of a non-responsive layer, a layer which is responsive to the presence of the particular liquid. Preferably, the polymer MEMS 10 are formed of should be biocompatible polymers such that they have minimal (bio)chemical interactions with the fluid in the micro-channels. Alternatively, the polymer actuator elements 71 may be modified so as to control non-specific adsorption properties and wettability. The polymer MEMS 10 may, for example, comprise a composite material. For example, it may comprise a particle-filled matrix material or a multilayer structure. It can also be mentioned that “liquid crystal polymer network materials” may be used in accordance with the present invention.

In a dry non-actuated state, i.e. when the actuator element is not in contact with a fluid and no external stimuli are applied to the actuator element, the polymer MEMS 10 which, in a specific example, may have the form of a beam or rod is preferably substantially straight.

In a wet non-actuated state, i.e. when liquid, e.g. water, is present and no other external stimuli are applied to the actuator element, the polymer MEMS 10 which, in a specific example, may have the form of a rod or beam or flap, are curved. During a wet actuated state, an external stimulus, such as, for example, an electric field such as a current, or a magnetic field applied to the polymer actuator elements 71, causes the actuator elements to straighten out or in other words, causes them to be set in motion. The change in shape of the actuator elements 71 sets the surrounding fluid, which is present in the micro-channel 62 of the micro-fluidic system, in motion. In FIGS. 1 and 2, the bending of the polymer MEMS 10 is indicated by arrow F₁. Due to the fixation to the wall 14 of one extremity of the actuator element 71 by attachment means 12 of the actuation element 71, the movement obtained resembles that of the movement of the cilia described earlier.

According to the above-described aspect of the invention, the polymer MEMS 10 may have a length L of between 10 and 200 μm and may typically be about 100 μm, and may have a width w of between 2 and 30 μm, typically about 20 μm. The polymer MEMS 10 may have a thickness t of between 0.1 and 2 μm, typically about 1 μm.

FIG. 6 illustrates an embodiment of a micro-channel 62 provided with polymer actuating means 71 according to the present invention. In this embodiment, an example of a design of part of a micro-fluidic system is shown. A cross-section of a micro-channel 62 is schematically depicted. According to this embodiment of the invention, the inner sides 61 of the walls 14 of the micro-channels 62, may be covered with a plurality of polymer actuator elements 71 bent because of the presence of liquid, e.g. water, in said micro-channel (upper part of FIG. 6). For the clarity of the drawings, only the polymer MEMS part 10 of the actuator element is shown. The polymer MEMS 10 can straighten and bend again repeatedly, under the action of an external stimulus applied to the actuator elements 71. This external stimulus may, as already discussed, for example be an electric field or a magnetic field. The actuator elements 71 may comprise polymer MEMS 10 which may e.g. have a rod-like shape or a beam-like shape, with their width extending in a direction coming out of the plane of the drawing.

The actuator elements 71 at the inner side 61 of the walls 14 of the micro-channels 62 may, in embodiments of the invention, be arranged in one or more rows. As an example only, the actuator elements 71 may be arranged in two rows of actuator elements 71, i.e. a first row of actuator elements 71 on a first position at the inner side 61 of the wall 14 and a second row of actuator elements at a second position of the inner side 61 of the wall 14, the first and second position being substantially opposite to each other, as illustrated in FIG. 6. In other embodiments of to the present invention, the actuator elements may also be arranged in a plurality of rows of actuator elements which may be arranged to form, for example, a two-dimensional array. In still further embodiments, the actuator elements 71 may be randomly positioned at the inner side 61 of the wall 14 of a micro-channel 62.

To be able to transport fluid in a certain direction, for example from the left to the right in FIG. 6, the movement of the polymer actuator elements must be asymmetric. That is, the nature of the “beating” stroke (the straightening) should be different from that of the “recovery” stroke (the bending)—beating stroke and recovery stroke being represented in FIG. 9. This may be achieved by a fast beating stroke and a much slower recovery stroke (or vice versa).

For a pumping device the motion of the polymer actuator elements 71 is provided by a metachronic actuator means. This can be done by providing means for addressing the actuator elements either individually or row by row. In case of, for example, electrostatic actuation this may be achieved by a patterned electrode structure that is part of a wall 14 of a microchannel 62. The patterned electrode structure may comprise a structured film, which film may be a metal or another suitable conductive film. Structuring of the film may be done by, for example, using lithography. The patterned structures can be individually addressed. The same may be applied for magnetically actuated structures. Patterned conductive films that are part of the channel wall structure may make it possible to create local magnetic fields so that actuator elements 71 can be addressed individually or in rows. In all above-described cases, individual or row-by-row stimulation of the actuator elements 71 is possible since the wall 14 of the micro-channel 62 comprises a structured pattern through which the stimulus is activated. By proper addressing in time, a co-ordinated stimulation, for example, in a wave-like manner, is made possible. Non-co-ordinated or random actuator means, symplectic metachronic actuator means and antiplectic metachronic actuator means are included within the scope of the present invention.

In the example shown in FIG. 6, all polymer actuator elements 71, also those on different rows, move simultaneously. The functioning of the polymer actuators may be improved by individual addressing of the actuator elements 71 or of the rows of actuator elements 71, so that their movement is out of phase. In, for example, electrically stimulated actuator elements 71, this may be performed by using patterned electrodes which may be integrated into the walls 14 of the micro-channel 62. Thus, the motion of actuator elements 71 may appear as a wave passing over the inner side 61 of the wall 14 of the micro-channel 62. The means for providing the movement may generate a wave movement that may pass in the same direction as the effective beating movement (“symplectic metachronism”) or in the opposite direction (“antiplectic metachronism”).

To, for example, obtain local mixing in a micro-channel 62 of a micro-fluidic system, the motion of the actuator elements 71 may be controlled in a specific manner, i.e. some actuator elements may move in one direction whereas other actuator elements may move in the opposite direction in a specific way so as to create local chaotic mixing. Vortices may be created by opposite movements of the actuator elements 71 on e.g. opposite positions of the walls 14 of the micro-channel 62.

Applying Blake's model (J. Blake in ‘A model for the micro-structure in ciliated organisms’, J. Fluid. Mech. 55, p. 1-23 (1972)) to the polymer actuator elements as described in embodiments of the present invention, it can be estimated that by covering the inner side 61 of a wall 14 of a micro-channel 62 with the actuator elements, a fluid flow with a velocity of between 0 and several mm/s, depending on the type of actuator elements and the fluid used, can be induced by controlling the movement of the actuator elements as described in the above embodiments. Taking, for example, water as a model fluid, it is also possible to compute that a load of 1 nN and a moment of 10⁻¹³ Nm must be applied to the actuator elements to reach this velocity. These are very small values, which can easily be obtained by the small components used in micro-fluidic systems. The above-described analysis proves that considerable velocities can be produced using the micro-fluidic systems according to embodiments of the present invention. Therefore, if the polymer MEMS 10 according to embodiments of the invention are designed so as to make a movement similar of that of cilia, the inner side 61 of walls 14 of micro-channels 62 comprising such polymer MEMS 10 will be very efficient in transporting and/or mixing of fluids and in creating vortices.

An advantage of the approach according to the present invention, in the specific case of polymer actuator elements 71, is that the means which takes care of fluid manipulation, i.e. the at least one polymer actuator element 71, is completely integrated in the micro-fluidic channel system and allows to obtain large shape changes that are required for micro-fluidic applications, so that no external pump or micro-pump is needed. Hence, the present invention provides compact micro-fluidic systems. Another, perhaps even more important advantage, is that the fluid can be controlled locally in the micro-channels 62 by addressing all actuator elements 71 at the same time or by addressing only at least one predetermined actuator element at a time. Therefore, fluid can be transported, re-circulated, mixed, or separated right at a required, predetermined position. A further advantage of the present invention is that the use of polymers for the actuator elements 71 may lead to cheap processing technologies such as, for example, printing or embossing techniques, or single-step lithography.

Furthermore, the micro-fluidic system according to the present invention is robust, this means that if a single or a few actuator elements 71 fail to work properly, that does not largely disturb the performance of the overall micro-fluidic system.

The micro-fluidic system according to the invention may be used in biotechnological applications, such as micro total analysis systems, micro-fluidic diagnostics, micro-factories and chemical or biochemical micro-plants, biosensors, rapid DNA separation and sizing, cell manipulation and sorting, in pharmaceutical applications, in particular high-throughput combinatorial testing where local mixing is essential, and in micro-channel cooling systems e.g. in micro-electronics applications.

For example, the micro-fluidic system of the present invention may be used in biosensors for, for example, the detection of at least one target molecule, such as proteins, antibodies, nucleic acids (e.g. DNR, RNA), peptides, oligo- or polysaccharides or sugars, in, for example, biological fluids, such as saliva, sputum, blood, blood plasma, interstitial fluid or urine. Therefore, a small sample of the fluid (e.g. a droplet) is supplied to the device, and by manipulation of the fluid within a micro-channel system, the fluid is let to the sensing position where the actual detection takes place. By using various sensors in the micro-fluidic system according to the present invention, different types of target molecules may be detected in one analysis run.

As mentioned earlier, the basic idea of the present invention is now to combine adaptation of the actuator elements so as to respond to the presence of a particular liquid by changing shape, so that a controlled curvature of actuator elements, e.g. made of films, is achieved by bringing them in a particular liquid environment (e.g. aqueous environment), with providing magnetic or electrostatic actuation mechanisms. Adapting the actuator elements so as to respond to the presence of a particular liquid by changing shape may be obtained by one of the three specific embodiments just described, or by similar methods. The actuation mechanisms may be provided in or on the actuating elements 71 by combining the materials required to induce the curvature with magnetic particles or magnetic layers for magnetic actuation, or with electrodes, for magnetic or electrostatic actuation.

The dry non-actuated state of the actuating elements 71 according to the present invention may be straight. When bringing the actuating elements 71 according to the present invention in a liquid-based, e.g. water-based, environment, the actuating elements 71 undergo the influence of the liquid and curve, so that their natural state or wet non-actuated state is curved with a radius of curvature determined by the material's molecular (or layered) structure. The actuating element 71 may be rolled out by magnetic or electrostatic actuation as described above, i.e. in wet actuated state, and returns to its natural curved state upon removal of the magnetic or electrostatic force, i.e. wet non-actuated state.

The movement of the actuator elements 71 may be measured by, for example, one or more magnetic sensors positioned in the micro-fluidic system. This may allow to determine flow properties such as, for example, flow speed and/or viscosity of the fluid in the micro-channel 62. Furthermore, other fluid details may be measured by using different actuation frequencies. For example, the cell content of the fluid, for example the hematocriet value, or the coagulation properties of the fluid, could be measured in that way.

An advantage of the above embodiment is that the use of magnetic or electrostatic actuation may work with very complex biological fluids such as e.g. saliva, sputum or full blood. Furthermore, magnetic or electrostatic actuation does not require contacts. In other words, magnetic or electrostatic actuation may be performed in a contactless way, i.e. when external magnetic field or electric field generating means are used, the actuator elements 10 themselves are inside the micro-fluidic cartridge while the external magnetic field or electric field generating means are positioned outside the micro-fluidic cartridge.

It is to be understood that although preferred embodiments, specific constructions and configurations, as well as materials, have been discussed herein for devices according to the present invention, various changes or modifications in form and detail may be made without departing from the scope and spirit of this invention.

1. A micro-fluidic system comprising:
at least one micro-channel (62) having a wall (14) with an inner side (61),
a plurality of ciliary actuator elements (71) attached to said inner side (61) of said wall (14), said ciliary actuator elements (71) having an original shape when not subjected to a liquid,
means for applying stimuli to said plurality of ciliary actuator elements (71) so as to cause a change in their shape from an initial shape to an end shape,
wherein said ciliary actuator elements (71) are adapted to respond to the presence of a particular liquid by changing their original shape into the initial shape.

2. A micro-fluidic system according to claim 1, wherein said particular liquid is water.

3. A micro-fluidic system according to claim 1, wherein the response to the presence of said particular liquid is a curving of the shape of the ciliary actuator element (71).

4. A micro-fluidic system according to claim 1, wherein the plurality of ciliary actuator elements are polymer actuator elements (71).

5. A micro-fluidic system according to claim 4, wherein the polymer actuator elements (71) comprise polymer MEMS.

6. A micro-fluidic system according to claim 5, wherein the polymer actuator elements (71) comprise at least one of the following:
a LC-polymer network material or/and
a gradient in polarity (44) over the thickness of the material used in said actuator or/and
a two-layer structure wherein one layer expands more in said particular liquid than the other.

7. A micro-fluidic system according to claim 1, wherein said means for applying a stimulus to said plurality of ciliary actuator elements (71) is one of an electric field generating means or a magnetic field generating means.

8. A micro-fluidic system according to claim 7, wherein said means for applying a stimulus to said ciliary actuator elements (71) is a magnetic field generating means.

9. A micro-fluidic system according to claim 8, wherein said ciliary actuator elements (71) furthermore comprise one of a uniform continuous magnetic layer (72), a patterned continuous magnetic layer or magnetic particles (81).

10. A micro-fluidic system according to claim 7, wherein said means for applying a stimulus to said ciliary actuator elements (71) is an electric field generating means.

11. A micro-fluidic system according to claim 10, wherein said ciliary actuator elements (71) furthermore comprise an electrode (11).

12. A micro-fluidic system according to claim 1, wherein said plurality of ciliary actuator elements (71) are arranged in a first and a second row, said first row of actuator elements (71) being positioned at a first position of said inner side (61) of said wall (14) and said second row of ciliary actuator elements (71) being positioned at a second position of said inner side (61) of said wall (14), said first position and said second position being substantially opposite to each other.

13. A micro-fluidic system according to claim 1, wherein said plurality of ciliary actuator elements (71) are arranged in a plurality of rows of ciliary actuator elements (71) which are arranged to form a two-dimensional array.

14. A micro-fluidic system according to claim 1, wherein said plurality of ciliary actuator elements (71) are randomly arranged at the inner side (61) of the wall (14).

15. A method for the manufacturing of a micro-fluidic system comprising at least one micro-channel (62), the method comprising:
providing an inner side (61) of a wall (14) of said at least one micro-channel (62) with a plurality of ciliary actuator elements (71), the ciliary actuator elements (71) having an original shape when not subjected to a liquid, and
providing means for applying a stimulus to said plurality of ciliary actuator elements (71) so as to cause a change in their shape from an initial shape to an end shape,
wherein said ciliary actuator elements (71) are adapted to respond to the presence of a particular liquid by changing their original shape into the initial shape.

16. A method according to claim 15, wherein providing said plurality of ciliary actuator elements (71) is performed by:
depositing a sacrificial layer having a length L on the inner side (61) of said wall (14),
depositing a actuator material on top of said sacrificial layer,
releasing said actuator material from said inner side (61) of said wall (14) by completely removing said sacrificial layer.

17. A method according to claim 16, wherein removing said sacrificial layer is done by performing an etching step.

18. A method according to claim 15, wherein said ciliary actuator elements (71) comprise at least one of the following:
a LC-polymer network material or/and
a gradient in polarity (44) over the thickness of the material used in said actuator or/and
a two-layer structure wherein one layer expands more in said liquid than the other.

19. A method according to claim 15, furthermore comprising providing said ciliary actuator elements (71) with one of a uniform continuous magnetic layer (72), a patterned continuous magnetic layer, or with magnetic particles (81).

20. A method according to claim 19, wherein providing means for applying a stimulus to said ciliary actuator elements (71) comprises providing a magnetic field generating means.

21. A method according to claim 15, furthermore comprising providing said ciliary actuator elements (71) with an electrode (11).

22. A method according to claim 21, wherein providing means for applying a stimulus to said ciliary actuator elements (71) comprises providing a electric field generating means.

23. A method for controlling a fluid flow through a micro-channel (62) of a micro-fluidic system, the micro-channel (62) having a wall (14) with an inner side (61), the method comprising:
providing said inner side (61) of said wall (14) with a plurality of ciliary actuator elements (71), the ciliary actuator elements (71) each having an original shape when not being subjected to a liquid,
applying a stimulus to said ciliary actuator elements (71) so as to cause a change in their shape, from an initial shape to an end shape, wherein said ciliary actuator elements (71) respond to the presence of a particular liquid by changing their original shape into the initial shape.

24. A method according to claim 23, wherein applying a stimulus to said ciliary actuator elements (71) is performed by applying a magnetic field.

25. A method according to claim 23, wherein applying a stimulus to said ciliary actuator elements (71) is performed by applying an electric field.

26. Use of the micro-fluidic system of claim 1 in biotechnological, pharmaceutical, electrical or electronic applications.

27. A micro-fluidic system comprising at least one micro-channel (62) having a wall (14) with an inner side (61) and containing a liquid, wherein the micro-fluidic system furthermore comprises:
a plurality of electroactive polymer actuator elements (71) attached to said inner side (61) of said wall (14), and
means for applying stimuli to said plurality of electroactive polymer actuator elements (71) to thereby drive the liquid in a direction along the micro-channel (62), wherein said ciliary actuator elements (71) respond to the presence of said liquid by changing shape.

28. A micro-fluidic system according to claim 27, wherein said plurality of electroactive polymer actuator elements (71) comprises a polymer gel or a Ionomeric Polymer-Metal Composite (IPMC).
